(19) United States
(12) Patent Application Publication
(10) Pub. No.: US 2026/0211035 A1
(43) Pub. Date: Jul. 23, 2026

(54) CONSISTENCY TESTING METHOD, DEVICE, APPARATUS, AND STORAGE MEDIUM FOR MEMORY STORAGE

(71) Applicant: Shenzhen Rayson Technology Co., Ltd., Shenzhen (CN)

(72) Inventor: Jun Wang, Shenzhen (CN)

(21) Appl. No.: 19/403,889

(22) Filed: Nov. 30, 2025

(30) Foreign Application Priority Data
Jan. 21, 2025 (CN) 202510093369X

(51) Int. Cl. G01R 31/3177

(52) U.S. Cl. CPC G01R 31/3177

(57) ABSTRACT

The application provides a consistency testing method, a device, an apparatus, and storage medium for a memory storage, which belong to the field of memory technology. The method includes: after initializing a target memory storage, determining target test ports from multiple data ports of the target memory storage and establishing test channels corresponding one-to-one with the target test ports; the data ports are provided with on-die termination (ODT) resistors corresponding one-to-one; respectively performing data interaction with the target memory storage through each test channel and determining DQ test data corresponding to the test channel; reading sampling data from the target memory storage, wherein the sampling data is obtained by sampling the data interaction process based on a data strobe signal (DQS) and corresponds one-to-one with the DQ test data.

### TECHNICAL FIELD

This application pertains to the field of memory technology, particularly relating to a consistency testing method, a device, an apparatus, and storage medium for memory storage.

### BACKGROUND

ODT (On-Die Termination, on-chip termination resistor) enables interference signals to be absorbed by the circuit's terminal, preventing them from reflecting on the circuit and adversely affecting data signal transmission. When ODT is configured in a memory storage (which is a memory based on DDR technology), it ensures that interference signals are fully absorbed by the circuit terminal, reducing the likelihood of reflections on the circuit and thereby enhancing the signal transmission quality of the memory storage. However, in practical applications, due to variations in the manufacturing processes of memory storage devices, the consistency of terminal impedance matching provided by the ODT in memory storage devices may not be satisfactory, leading to impedance matching failure. Therefore, how to quickly identify ODTs with inconsistent terminal impedance matching is a pressing technical issue that needs to be resolved.

### SUMMARY

The main objective of the embodiments in this application is to propose a consistency testing method, a device, an apparatus, and storage medium for memory storage, which can swiftly identify ODTs with inconsistent terminal impedance matching.

In order to achieve the aforementioned objective, the first aspect of the embodiments in this application proposes a consistency testing method for memory storage. The method comprises the following steps:
initializing a target memory storage, wherein the target memory storage is equipped with multiple data ports and on-die termination (ODT) resistors corresponding one-to-one to the data ports;
determining target test ports from the multiple data ports and establishing test channels corresponding one-to-one to the target test ports;
performing data interaction with the target memory storage through each of the test channels respectively, and determining data bus signal (DQ) test data corresponding to the test channels;
reading sampling data from the target memory storage, wherein the sampling data is obtained by the target memory storage sampling the data interaction process based on a data strobe signal (DQS), and the sampling data corresponds one-to-one to the DQ test data;
performing an exclusive-NOR operation on the sampling data and the corresponding DQ test data to obtain a target eye diagram for each test channel;
determining whether the corresponding ODTs meet preset consistency conditions based on the target eye diagrams, and outputting consistency test results according to the determination results of each ODT.

In order to achieve the aforementioned objective, the second aspect of the embodiments in this application proposes a consistency testing device for memory storage, which comprises:
an initialization module configured to initialize a target memory storage, wherein the target memory storage is equipped with multiple data ports and on-die termination (ODT) resistors corresponding one-to-one to the data ports;
a communication connection module configured to determine target test ports from the multiple data ports and establish test channels corresponding one-to-one to the target test ports;
an interaction module configured to perform data interaction with the target memory storage through each of the test channels respectively, and determine data bus signal (DQ) test data corresponding to the test channels;
a sampling data acquisition module configured to read sampling data from the target memory storage, wherein the sampling data is obtained by the target memory storage sampling the data interaction process based on a data strobe signal (DQS), and the sampling data corresponds one-to-one to the DQ test data;
an eye diagram generation module configured to perform an exclusive-NOR operation on the sampling data and the corresponding DQ test data to obtain a target eye diagram for each test channel;
a result verification module configured to determine, based on the target eye diagrams, whether the corresponding ODTs meet preset consistency conditions, and output consistency test results according to the determination results of each ODT.

In order to achieve the aforementioned objectives, the third aspect of the embodiments in this application proposes an electronic apparatus. The electronic apparatus comprises a memory and a processor. The memory stores a computer program, and when executed by the processor, the computer program implements the consistency testing method for memory storage as described in any one of the embodiments of the first aspect.

In order to achieve the aforementioned objectives, the fourth aspect of the embodiments in this application proposes a computer-readable storage medium. The storage medium stores a computer program, and when executed by a processor, the computer program implements the consistency testing method for memory storage as described in any one of the embodiments of the first aspect. proposed in this application construct target eye diagrams based on DQ test data and sampling data from target data ports. This approach enables direct and continuous testing of multiple target data ports on the target memory storage without relying on third-party testing tools, while simultaneously generating relevant target eye diagrams, resulting in higher testing efficiency. The target eye diagrams provide a more intuitive visualization of whether DQ data undergoes changes during transmission due to ODT impedance mismatching. Furthermore, by utilizing pre-configured consistency conditions, the target eye diagrams can be automatically matched with these conditions, thereby outputting consistency test results for each ODT. This further reduces the need for human involvement in the testing process. Therefore, compared to related technologies, the embodiments in this application can more swiftly identify ODTs with inconsistent terminal impedance matching.

### BRIEF DESCRIPTION OF THE DRAWINGS

FIG. 1 is a schematic flowchart of the consistency testing method for memory storage provided in this application;

FIG. 2 is a schematic diagram illustrating an application scenario of the consistency testing method for memory storage provided in this application;

FIG. 3 is a schematic diagram showing the interaction between a memory storage and a testing platform in an embodiment of the consistency testing method for memory storage provided in this application;

FIG. 4 is a modular schematic diagram of the consistency testing device for memory storage provided in this application;

FIG. 5 is a structural schematic diagram of the hardware architecture corresponding to the consistency testing method for memory storage provided in this application.

### DETAILED DESCRIPTION

In order to make the objectives, technical solutions, and advantages of this application clearer and more comprehensible, this application is further elaborated in detail below in conjunction with the accompanying drawings and embodiments. It should be understood that the specific embodiments described herein are merely intended to explain this application and are not intended to limit it.

It should be noted that although functional module divisions are made in the apparatus schematic diagrams and logical sequences are shown in the flowcharts, in certain cases, the steps illustrated or described may be executed in a sequence different from the module divisions in the apparatus or the sequence in the flowcharts. The terms “first,” “second,” etc., used in the specification, claims, and the aforementioned drawings are for distinguishing similar objects and are not necessarily used to describe a specific order or sequence.

Unless otherwise defined, all technical and scientific terms used herein have the same meanings as commonly understood by those skilled in the technical field to which this application belongs. The terms used herein are merely for the purpose of describing the embodiments of this application and are not intended to limit it.

First, several terms involved in this application are explained as follows.
DDR, which stands for Double Data Rate Synchronous Dynamic Random Access Memory.
ODT (On-Die Termination, on-chip termination resistor), enables interference signals to be absorbed by the circuit's terminal, preventing them from reflecting on the circuit and adversely affecting data signal transmission. When ODT is configured in a memory storage (where the memory storage is a memory based on DDR technology), it ensures that interference signals are fully absorbed by the circuit terminal, reducing the likelihood of reflections on the circuit and thereby enhancing the signal transmission quality of the memory storage. However, in practical applications, due to variations in the manufacturing processes of memory storage devices, the consistency of terminal impedance matching provided by the ODT in memory storage devices may not be satisfactory, leading to impedance matching failure. Therefore, how to swiftly identify ODTs with inconsistent terminal impedance matching is a pressing technical issue that needs to be resolved. Based on this, the embodiments of this application provide a consistency testing method, a device, an apparatus, and storage medium for memory storage, which can swiftly identify ODTs with inconsistent terminal impedance matching.

The consistency testing method, a device, an apparatus, and storage medium for memory storage provided in the embodiments of this application are specifically illustrated through the following embodiments. First, the consistency testing method for memory storage in the embodiments of this application is described.

The consistency testing method for memory storage in this application can be applied in numerous general-purpose or dedicated computer system environments or configurations, such as personal computers, server computers, handheld or portable devices, tablet devices, multiprocessor systems, and so on. This application can be described within the general context of computer-executable instructions executed by a computer, such as program modules. Generally, program modules include routines, programs, objects, components, data structures, etc., that perform specific tasks or implement specific abstract data types. This application can also be practiced in distributed computing environments, where tasks are executed by remote processing devices connected through a communication network. In distributed computing environments, program modules can be located in both local and remote computer storage media, including storage devices.

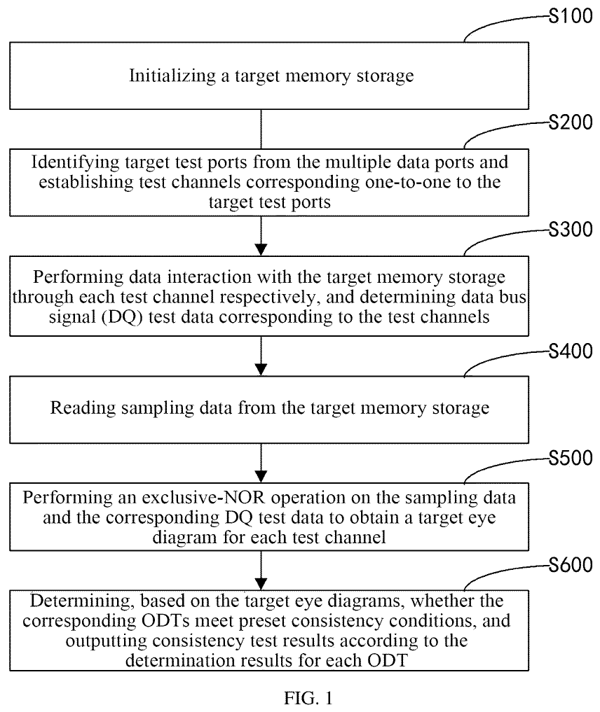

It can be understood that, with reference to FIG. 1, a consistency testing method for memory storage provided in accordance with an embodiment of this application includes the following steps:
Step S100: initializing a target memory storage, which is equipped with multiple data ports and on-die termination (ODT) resistors corresponding one-to-one to the data ports;
Step S200: identifying target test ports from the multiple data ports and establishing test channels corresponding one-to-one to the target test ports;
Step S300: performing data interaction with the target memory storage through each test channel respectively, and determining data bus signal (DQ) test data corresponding to the test channels;
Step S400: reading sampling data from the target memory storage, wherein the sampling data is obtained by the target memory storage sampling the data interaction process based on a data strobe signal (DQS), the sampling data corresponds one-to-one to the DQ test data.

Step S500: performing an exclusive-NOR operation on the sampling data and the corresponding DQ test data to obtain a target eye diagram for each test channel;

Step S600: determining, based on the target eye diagrams, whether the corresponding ODTs meet preset consistency conditions, and outputting consistency test results according to the determination results for each ODT.

Therefore, by constructing target eye diagrams based on DQ test data and sampling data from target data ports, this approach enables direct and continuous testing of multiple target data ports on the target memory storage without relying on third-party testing tools, while simultaneously generating relevant target eye diagrams, resulting in higher testing efficiency. Moreover, the target eye diagrams provide a more intuitive visualization of whether DQ data undergoes changes during transmission due to ODT impedance mismatching. Additionally, by utilizing pre-configured consistency conditions, the target eye diagrams can be automatically matched with these conditions, thereby outputting consistency test results for each ODT. This further reduces the need for human involvement in the testing process. Therefore, the embodiments of this application can more swiftly identify ODTs with inconsistent terminal impedance matching.

The embodiments of this application do not impose any restrictions on the number of target test ports. Those skilled in the art may choose to designate each data port of the target memory storage as a target test port or select only some of the data ports as target test ports.

Data interaction includes at least one of read operation interaction and write operation interaction, and those skilled in the art may select one for data interaction based on actual needs.

The embodiments of this application do not involve any changes to the initialization of the target memory storage, and there are no restrictions on how the target memory storage is initialized. Those skilled in the art may set it up selectively based on actual needs.

The port provided by the target memory storage for reading sampling data is different from the port of the test channel. DQ does not affect the data channel constructed by the port for reading sampling data.

The embodiments of this application do not impose any restrictions on the quantity or content of DQ test data on the same test channel. Those skilled in the art may set them up selectively based on actual circumstances.

After performing an exclusive-NOR operation on each sampling data and its corresponding DQ test data, a set of data composed of 0s and 1s, with the same length as the DQ test data, can be obtained. At this point, a target eye diagram can be generated based on this data. The embodiments of this application do not involve the method of generating a target eye diagram based on data composed of 0s and 1s, so no further elaboration is provided here.

Each target eye diagram corresponds one-to-one with DQ test data. The number of target eye diagrams is determined by the number of test channels and the quantity of DQ test data on each test channel. For example, if there are three test channels, namely Test Channel 1, Test Channel 2, and Test Channel 3, with 10 DQ test data set on Test Channel 3, 2 on Test Channel 2, and 7 on Test Channel 1, then there will be 10 target eye diagrams for Test Channel 3, 2 for Test Channel 2, and 7 for Test Channel 1. In this round of testing, the total number of target eye diagrams will be 10+2+7=19.

Whether the ODT meets the consistency conditions can be determined by comparing at least one parameter, such as the area ratio, dimensions (length and width), and shape similarity between the target eye diagram and the expected eye diagram.

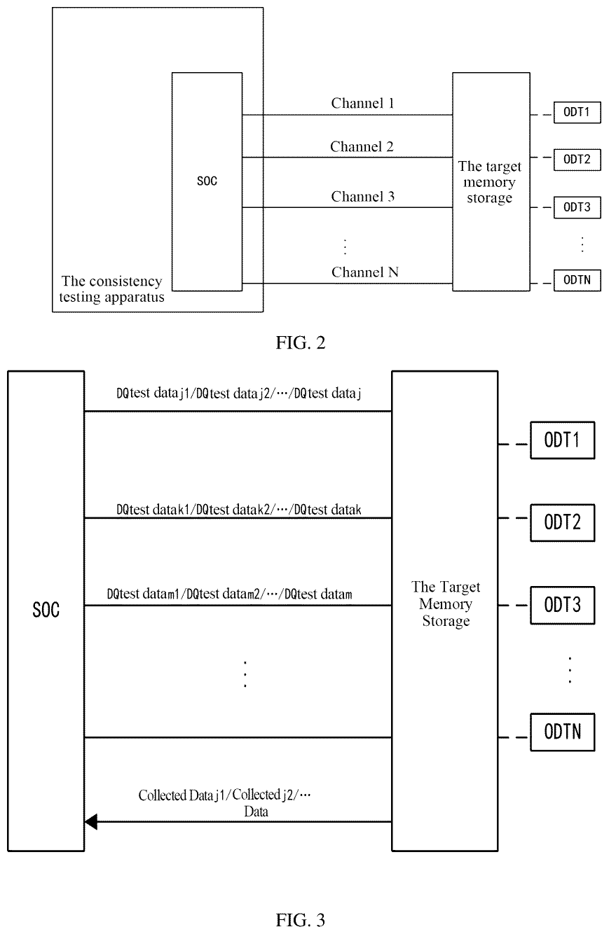

Exemplarily, taking the scenario where each data port of the target memory storage serves as a target test port as an example, as shown in FIG. 2, the consistency testing device, functioning as a testing platform, is integrated with an SOC interface that interacts with the target memory storage. The target memory storage is provided with N data ports, and N test channels can be established accordingly, labeled as Channel 1 to Channel N. Each test channel is configured to test one ODT. As depicted in FIG. 2, Channel 1 can measure whether ODT1 meets the consistency conditions, Channel 2 can measure whether ODT2 meets the consistency conditions, and Channel N can measure whether ODTN meets the consistency conditions.

It can be understood that performing data interaction with the target memory storage through each test channel respectively, as well as determining the data bus signal (DQ) test data corresponding to the test channels, comprises:
writing preset signal data to the target memory storage through each test channel respectively, and using the signal data as the DQ test data for the corresponding test channel;
writing simulated test data to the target memory storage through each test channel respectively, and reading the previously written simulated test data from the target memory storage through each test channel to obtain the DQ test data corresponding to the test channels.

By conducting tests involving both read and write operations on each test channel, it is possible to cover interference scenarios that may occur in actual situations as comprehensively as possible, thereby ensuring the accuracy of ODT consistency determination.

The embodiments of this application do not impose any restrictions on the number of test channels engaged in data interaction simultaneously, nor do they restrict whether the data interaction on each test channel at the same time involves write or read operations. Those skilled in the art can selectively combine these operations based on actual requirements to meet testing needs.

It can be understood that when there are multiple test channels, performing data interaction with the target memory storage through each test channel respectively, comprises:
creating test threads that correspond one-to-one with the test channels;
Synchronously invoking each created test thread to enable data interaction between each test thread and the target memory storage through the corresponding test channel.

By configuring multiple test threads, it is possible to enhance testing efficiency while also increasing the number of combinations for data interaction across test channels, thereby covering more scenarios.

In some other embodiments, corresponding acquisition threads are also created for the collected data. By synchronously executing the acquisition threads with the test threads, the efficiency of ODT consistency determination can be accelerated.

Exemplarily, as shown in FIG. 3, for N test channels, each test channel can interact with DQ test data through its corresponding test thread. Simultaneously, the collected data, such as j1, which corresponds one-to-one with the DQ test data, is collected through its corresponding acquisition thread.

It can be understood that a single test channel may correspond to multiple target eye diagrams; the DQ test data corresponding to these multiple target eye diagrams within the same test channel are identical; determining whether the corresponding ODT meets the preset consistency conditions based on the target eye diagrams, comprising:
performing eye diagram averaging on each target eye diagram corresponding to the same DQ test data within the same test channel to obtain an averaged eye diagram;
updating the target eye diagrams of the corresponding test channel based on the averaged eye diagram and the remaining non-averaged target eye diagrams in the corresponding test channel;
determining whether the corresponding ODT meets the consistency conditions based on the updated target eye diagrams.

By initially performing eye diagram averaging, each type of DQ test data corresponds to a single target eye diagram for determining the ODT's consistency conditions, thereby reducing the computational complexity of the consistency condition determination.

It can be understood that performing eye diagram averaging on each target eye diagram corresponding to the same DQ test data within the same test channel to obtain an averaged eye diagram, comprising:
obtaining the distribution trend of each target eye diagram corresponding to the same DQ test data within the same test channel;
deleting target eye diagrams outside the preset distribution range based on the distribution trend to update the target eye diagrams of the test channel;
calculating the distance mean based on the coordinate points of each target eye diagram corresponding to the same DQ test data within the updated same test channel to obtain the averaged eye diagram.

For example, if 80% of the target eye diagrams corresponding to the same DQ test data within the same test channel are distributed within a range of length [x1, x2] and width [y1, y2], it indicates that eye diagrams outside this distribution range may be anomalies caused by other factors. This approach can thus eliminate anomalies not caused by the ODT's inherent functionality, further improving the accuracy of ODT consistency determination. The embodiments of this application do not impose restrictions on how the distribution range is set; those skilled in the art can set it selectively based on actual circumstances.

Calculating the distance mean of the coordinate points of each target eye diagram involves, for example, calculating the mean of the y-coordinates of coordinate points with the same x-coordinate along the x-axis, or calculating the mean of the x-coordinates of coordinate points with the same y-coordinate along the y-axis.

It can be understood that a single test channel may correspond to multiple target eye diagrams; determining whether the corresponding ODT meets the preset consistency conditions based on the target eye diagrams, comprises:
obtaining eye diagram thresholds corresponding to each ODT based on the consistency conditions;
comparing each target eye diagram with its corresponding eye diagram threshold to obtain comparison results;
determining the proportion of target eye diagrams that meet the preset eye diagram threshold conditions for each ODT based on the comparison results;
determining that the corresponding ODT meets the consistency conditions when the proportion of target eye diagrams exceeds a preset threshold proportion.

The eye diagram thresholds may include at least one of an eye diagram area threshold, a length threshold, and a width threshold. When multiple eye diagram thresholds are set, failure to meet any one indicates that the target eye diagram does not meet the eye diagram threshold conditions.

For example, suppose there are 10 target eye diagrams for ODT1, labeled as Eye Diagram 1 to Eye Diagram 10, and the eye diagram thresholds include an eye diagram area threshold and a width threshold. If Eye Diagram 1 meets the eye diagram area threshold but not the width threshold, it is determined that Eye Diagram 1 does not meet the preset eye diagram threshold conditions. Similarly, the conditions for other eye diagrams can be determined. Assuming that 4 out of Eye Diagram 1 to Eye Diagram 10 do not meet the preset eye diagram threshold conditions, the proportion of target eye diagrams is 6/10=0.6. If 0.6 exceeds the threshold proportion, it is determined that ODT1 meets the consistency conditions. If 0.6 is less than or equal to the threshold proportion, it is determined that ODT1 does not meet the preset threshold conditions.

By setting a threshold proportion, it is possible to further reduce testing anomalies caused by other interfering factors and improve the accuracy of ODT determination.

It can be understood that when there are multiple target memory storages, outputting consistency test results based on the determination results of each ODT, comprises:
obtaining the determination results of each ODT and determining the deviation values of each ODT based on the determination results;
displaying the deviation values of the ODTs corresponding to each data port in a preset deviation coordinate system using preset rendering colors; wherein the rendering colors for the same data port across different types of target memory storages are identical, and the rendering colors for different data ports within the same target memory storage are different.

The deviation values may be area deviation values, dimensional deviation values (such as length deviation values or width deviation values), or a combination of any one or two of the area deviation values, length deviation values, and width deviation values. The embodiments of this application do not impose restrictions on this; those skilled in the art can set them selectively based on actual circumstances.

By using the same rendering color for the same data port, the impact trend of ODTs at the same position on memory storage transmission can be observed. Displaying the deviation values of each data port allows for further observation of the magnitude of deviations at each data port, thereby determining the direction for calibration.

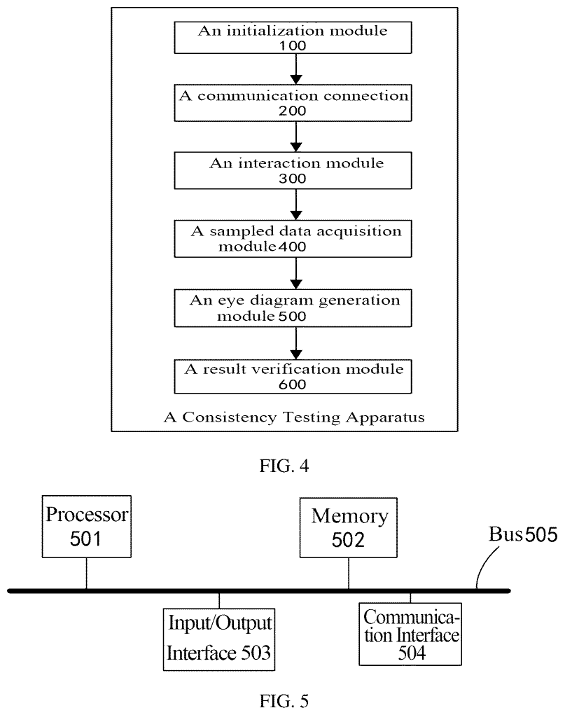

It can be understood that, with reference to FIG. 4, a consistency testing device for a memory storage provided in accordance with this application comprises:
an initialization module 100 configured to initialize a target memory storage, where the target memory storage is equipped with multiple data ports and corresponding on-die termination (ODT) resistors that are in one-to-one correspondence with the data ports;
a communication connection module 200 configured to identify target test ports from among the multiple data ports and establish test channels that are in one-to-one correspondence with the target test ports;
an interaction module 300 configured to perform data interaction with the target memory storage through each test channel, respectively, and to determine DQ (Data Bus Signal) test data corresponding to the test channels;
a sampled data acquisition module 400 configured to read sampled data from the target memory storage; the sampled data is obtained by the target memory storage through sampling the data interaction process based on a data strobe signal (DQS); the sampled data and the DQ test data are in one-to-one correspondence;
an eye diagram generation module 500 configured to perform an XNOR (exclusive NOR) operation on the sampled data and the corresponding DQ test data to obtain target eye diagrams corresponding to each test channel;
a result verification module 600 configured to determine, based on the target eye diagrams, whether the corresponding ODTs meet preset consistency conditions, and to output consistency test results based on the determination results for each ODT.

This application also provides an electronic apparatus, which includes a memory and a processor. The memory stores computer programs, and when executed by the processor, these programs implement the aforementioned consistency testing method for memory storage. This electronic apparatus can be any intelligent terminal, including but not limited to tablets and in-vehicle computers.

Please refer to FIG. 5, which illustrates the hardware structure of an electronic apparatus in another embodiment. The electronic apparatus comprises:
a processor 501, which can be implemented using a general-purpose CPU (Central Processing Unit), a microprocessor, an Application-Specific Integrated Circuit (ASIC), or one or more integrated circuits; wherein the processor 501 is configured to execute relevant programs to implement the technical solutions provided in the embodiments of this application;
a memory 502, which can be NAND flash. Relevant program code is stored in the memory 502, and the processor 501 invokes and executes the consistency testing method for memory storage as described in the embodiments of this application;
an input/output interface 503 configured to input and output information. a communication interface 504 configured to interact communication between this device and other devices; wherein communication can be achieved through wired means (such as USB, network cables, etc.) or wireless means (such as mobile networks, Wi-Fi, Bluetooth, etc.);
a bus 505, which transmits information among various components of the device (such as the processor 501, memory 502, input/output interface 503, and communication interface 504).

The processor 501, the memory 502, the input/output interface 503, and the communication interface 504 are interconnected for internal communication within the device via the bus 505.

The embodiments of this application also provide a computer-readable storage medium. This computer-readable storage medium stores a computer program that, when executed by a processor, implements the aforementioned consistency testing method for memory storage.

As a non-transitory computer-readable storage medium, the memory can be used to store non-transitory software programs and non-transitory computer-executable programs. Additionally, the memory may include high-speed random-access memory and may also comprise non-transitory memory, such as at least one magnetic disk storage device, a flash memory device, or other non-transitory solid-state storage devices. In some implementations, the memory may optionally comprise memory located remotely from the processor, and these remote memories can be connected to the processor via a network. Examples of such networks include, but are not limited to, the Internet, intranets, local area networks, mobile communication networks, and combinations thereof.

The embodiments described in this application are intended to provide a clearer illustration of the technical solutions provided herein and do not constitute limitations on these solutions. Those skilled in the art will appreciate that as technology evolves and new application scenarios emerge, the technical solutions provided in this application will also be applicable to similar technical problems.

It should be understood by those skilled in the art that the technical solutions depicted in the figures do not constitute limitations on the embodiments of this application. These solutions may include more or fewer steps than illustrated, or may combine certain steps, or involve different steps. The apparatus embodiments described above are merely illustrative. The units described as separate components may or may not be physically separated, meaning they can be located in a single place or distributed across multiple network units. Depending on actual needs, some or all of the modules can be selected to achieve the objectives of the present embodiment.

Those of ordinary skill in the art can appreciate that all or some of the steps in the methods disclosed above, as well as the functional modules/units in systems and devices, can be implemented as software, firmware, hardware, or appropriate combinations thereof.

The terms “first,” “second,” “third,” “fourth,” etc. (if present) in the specification and the accompanying drawings of this application are used to distinguish similar objects and are not necessarily intended to describe a specific order or sequence. It should be understood that the data used in this manner can be interchanged where appropriate, so that the embodiments of this application described herein can be implemented in sequences other than those illustrated or described here. Furthermore, the terms “include” and “have,” as well as any variations thereof, are intended to cover non-exclusive inclusions. For example, a process, method, system, product, or device that includes a series of steps or units is not necessarily limited to those steps or units clearly listed but may include other steps or units not clearly listed or inherent to such processes, methods, products, or devices.

It should be understood that in this application, “at least one (item)” refers to one or more, and “multiple” refers to two or more. The term “and/or” is used to describe the associative relationship between associated objects, indicating that three relationships may exist. For example, “A and/or B” can represent three scenarios: the presence of only A, the presence of only B, and the simultaneous presence of both A and B, where A and B can be singular or plural. The character “/” generally indicates that the associated objects before and after it have an “or” relationship. “At least one (item) of the following” or similar expressions refer to any combination of these items, including any combination of a single item or multiple items. For example, at least one of a, b, or c can represent a, b, c, “a and b,” “a and c,” “b and c,” or “a and b and c,” where a, b, and c can be singular or multiple.

In the several embodiments provided by this application, it should be understood that the disclosed devices and methods can be implemented in other ways. For example, the device embodiments described above are merely illustrative. The division of the aforementioned units is merely a logical functional division, and alternative division methods may be employed in actual implementations. For instance, multiple units or components may be combined or integrated into another system, or some features may be omitted or not executed. Additionally, the coupling or direct coupling or communication connection shown or discussed between objects may be indirect coupling or communication connection through some interfaces, devices, or units, which may be electrical, mechanical, or in other forms.

The units described as separate components may or may not be physically separated, and the components displayed as units may or may not be physical units. That is, they can be located in a single place or distributed across multiple network units. Depending on actual needs, some or all of the units can be selected to achieve the objectives of the present embodiment.

Furthermore, the functional units in each embodiment of this application can be integrated into a single processing unit or can exist as separate physical units. Alternatively, two or more units can be integrated into a single unit. The aforementioned integrated units can be implemented in the form of hardware or as software functional units.

If the integrated unit is implemented in the form of a software functional unit and sold or used as an independent product, it can be stored in a computer-readable storage medium. Based on this understanding, the technical solutions of this application, either in essence or in terms of their contributions to the existing technology, or part or all of the technical solutions, can be embodied in the form of a software product. This computer software product is stored in a storage medium and includes multiple instructions to enable a computer device (which can be a personal computer, server, network device, etc.) to execute all or part of the steps of the methods described in each embodiment of this application. The aforementioned storage medium includes various media capable of storing programs, such as USB drives, mobile hard drives, read-only memory (ROM), random-access memory (RAM), magnetic disks, or optical disks.

The preferred embodiments of this application have been described above with reference to the accompanying drawings, but this does not limit the scope of rights of this application. Any modifications, equivalent substitutions, and improvements made by those skilled in the art without departing from the scope and essence of this application should fall within the scope of rights of this application.

1. A consistency testing method for a memory storage, comprising:
initializing a target memory storage, wherein the target memory storage is provided with multiple data ports and on-die termination (ODT) resistors corresponding one-to-one with the data ports;
determining target test ports from the multiple data ports and establishing test channels corresponding one-to-one with the target test ports;
respectively performing data interaction with the target memory storage through each test channel and determining data bus signal DQ test data corresponding to the test channel;
reading sampling data from the target memory storage; the sampling data is data obtained by the target memory storage sampling the data interaction process based on a data strobe signal DQS; the sampling data and the DQ test data correspond one-to-one;
performing an exclusive-NOR operation on the sampling data and the corresponding DQ test data to obtain a target eye diagram corresponding to each test channel;
determining whether the corresponding ODT meets a preset consistency condition based on the target eye diagram, and outputting a consistency test result according to the determination results of each ODT;
wherein multiple target eye diagrams corresponding to the same test channel are provided; the DQ test data corresponding to the multiple target eye diagrams in the same test channel is the same; the determining whether the corresponding ODT meets a preset consistency condition based on the target eye diagram, comprises:
performing eye diagram averaging processing on each target eye diagram corresponding to the same DQ test data in the same test channel to obtain an average eye diagram;
updating the target eye diagrams of the corresponding test channel based on the average eye diagram and the remaining target eye diagrams in the corresponding test channel that have not undergone averaging processing;
determining whether the corresponding ODT meets the consistency condition based on the updated target eye diagrams;
wherein the performing eye diagram averaging processing on each target eye diagram corresponding to the same DQ test data in the same test channel to obtain an average eye diagram, comprises:
acquiring the distribution trend of each target eye diagram corresponding to the same DQ test data in the same test channel;
deleting target eye diagrams outside a preset distribution range to update the target eye diagrams of the test channel according to the distribution trend;
calculating the distance average based on the coordinate points of each updated target eye diagram corresponding to the same DQ test data in the same test channel to obtain the average eye diagram;
wherein multiple target memory storages are provided, and the outputting the consistency test result according to the determination results of each ODT, comprises:
acquiring the determination results of each ODT and determining the deviation values of each ODT according to the determination results;
displaying the deviation values of the ODTs corresponding to each data port in a preset deviation coordinate system using preset rendering colors; wherein the rendering colors of the same data ports in different types of target memory storages are the same, and the rendering colors of different data ports in the same target memory storage are different.

2. The consistency testing method for the memory storage according to claim 1, wherein the respectively performing data interaction with the target memory storage through each test channel and determining data bus signal DQ test data corresponding to the test channel, comprises:
respectively writing preset signal data to the target memory storage through each test channel and using the signal data as the DQ test data of the corresponding test channel;
respectively writing simulated test data to the target memory storage through each test channel and reading previously written simulated test data from the target memory storage through each test channel to obtain the DQ test data corresponding to the test channel.

3. The consistency testing method for a memory storage according to claim 1, wherein multiple test channels are provided, and the respectively performing data interaction with the target memory storage through each test channel, comprises:
creating test threads corresponding one-to-one with the test channels;
synchronously invoking each created test thread so that each test thread performs data interaction with the target memory storage through the corresponding test channel.

4. The consistency testing method for the memory storage according to claim 1, wherein the determining whether the corresponding ODT meets a preset consistency condition based on the target eye diagram, comprises:
acquiring eye diagram thresholds corresponding to each ODT according to the consistency condition;
for each target eye diagram, comparing the target eye diagram with the corresponding eye diagram threshold to obtain a comparison result;
determining the proportion of target eye diagrams based on each comparison result, when each ODT meets the preset eye diagram threshold;
determining that the corresponding ODT meets the consistency condition when the proportion of target eye diagrams is greater than a preset threshold proportion.

5. A consistency testing device for a memory storage, comprising:
an initialization module configured to initialize a target memory storage, wherein the target memory storage is provided with multiple data ports and on-die termination (ODT) resistors corresponding one-to-one with the data ports;
a communication connection module configured to determine target test ports from the multiple data ports and establish test channels corresponding one-to-one with the target test ports;
an interaction module configured to respectively perform data interaction with the target memory storage through each test channel and determine data bus signal DQ test data corresponding to the test channel;
a sampling data acquisition module configured to read sampling data from the target memory storage; the sampling data is data obtained by the target memory storage sampling the data interaction process based on a data strobe signal DQS; the sampling data and the DQ test data correspond one-to-one;
an eye diagram generation module configured to perform an exclusive-NOR operation on the sampling data and the corresponding DQ test data to obtain a target eye diagram corresponding to each test channel;
a result verification module configured to determine whether the corresponding ODT meets a preset consistency condition based on the target eye diagram, and output a consistency test result according to the determination results of each ODT;
wherein multiple target eye diagrams corresponding to the same test channel are provided; the DQ test data corresponding to the multiple target eye diagrams in the same test channel is the same; the result verification module is further configured to comprise:
acquiring the distribution trend of each target eye diagram corresponding to the same DQ test data in the same test channel;
deleting target eye diagrams outside a preset distribution range to update the target eye diagrams of the test channel according to the distribution trend;
calculating the distance average based on the coordinate points of each updated target eye diagram corresponding to the same DQ test data in the same test channel to obtain the average eye diagram;
updating the target eye diagrams of the corresponding test channel based on the average eye diagram and the remaining target eye diagrams in the corresponding test channel that have not undergone averaging processing;
determining whether the corresponding ODT meets the consistency condition based on the updated target eye diagrams;
wherein multiple target memory storages are provided, the result verification module is further configured to comprise:
acquiring the determination results of each ODT and determining the deviation values of each ODT according to the determination results;
displaying the deviation values of the ODTs corresponding to each data port in a preset deviation coordinate system using preset rendering colors; wherein the rendering colors of the same data ports in different types of target memory storages are the same, and the rendering colors of different data ports in the same target memory storage are different.

6. An electronic apparatus, wherein the electronic apparatus comprises a memory and a processor, wherein the memory stores a computer program, and the processor, when executing the computer program, implements the consistency testing method for a memory storage according to claim 1.
